(19) United States
(12) Patent Application Publication
(10) Pub. No.: US 2011/0056732 A1
(43) Pub. Date: Mar. 10, 2011

(54) FLEX-RIGID WIRING BOARD AND METHOD FOR MANUFACTURING THE SAME

(76) Inventor: Atsuhiro Uratsuji, Ishikawa (JP)

(21) Appl. No.: 12/990,821

(22) PCT Filed: May 1, 2009
(86) PCT No.: PCT/JP2009/058565

§ 371 Date: Nov. 3, 2010

(30) Foreign Application Priority Data
May 8, 2008 (JP) 2008-121791

(51) Int. Cl. H05K 1/00; B05D 5/12; C25D 7/00

(52) U.S. Cl. 174/254; 427/96.2; 205/125

(57) ABSTRACT

Provided are a flex-rigid wiring board in which resin that is easily affected by chemicals can be protected reliably without any increase in the number of manufacturing process steps, and a method for manufacturing the flex-rigid wiring board. The flex-rigid wiring board consists of a flexible section (A) and a rigid section (B). The flexible section (A) includes a base film (24) which is an insulating layer and a sheet of copper foil (26) which is a conductor layer. The rigid section (B) is provided integrally with the flexible section (A) and includes circuit patterns (28, 29). One surface of the base film (24) of the flexible section (A) is entirely covered with the sheet of copper foil (26). The sheet of copper foil (26) is removed by etching during an intermediate process step. At a boundary of the flexible section (A) and the rigid section (B), a portion extending from the removed sheet of copper foil (26) located into the rigid section (B).

### TECHNICAL FIELD

The present invention relates to a flex-rigid wiring board including a flexible cable section which is integrally formed with and extends from a mounting section on which various electronic circuits are mounted. The present invention also relates to a method for manufacturing the flex-rigid wiring board.

### BACKGROUND ART

Flexible wiring boards with necessary wiring patterns formed on a surface of an insulating film have been used in various types of equipment. Especially in recent years, flex-rigid wiring boards consisting of a rigid mounting section on which electronic circuits are mounted and a flexible cable section extending from the mounting section have been used frequently in various types of electronic equipment.

As illustrated in FIGS. 3A to 3D, a flex-rigid wiring board 2 consists of a flexible section A in which cables are wired and a rigid section B on which circuits and electric elements are mounted. The flexible section A and the rigid section B are formed integrally with each other. The flex-rigid wiring board 2 includes a copper clad laminate 10 extending continuously between the flexible section A and the rigid section B. The copper clad laminate 10 is constituted by a base film 4 which is a core substrate and sheets of copper foil 6 provided on both sides of the base film 4. The sheets of copper foil 6 are etched to form predetermined circuit patterns 8. Cover lay film(s) 12 are attached to the circuit pattern(s) 8 on one or both sides of the base film 4. An insulating layer 14 formed of, for example, a glass-epoxy prepreg is laminated over the cover lay film 12. Similarly, an insulating layer 15 formed of, for example, a prepreg is laminated over the circuit pattern 8 on the other side. The insulating layers 14 and 15 are laminated with sheets of copper foil 16. A via hole 18, a through hole and other holes are formed such that the sheets of copper foil 16 might be patterned to form predetermined circuits.

A method for manufacturing the flex-rigid wiring board 2 is as follows: First, as illustrated in FIG. 3A, a copper clad laminate 10 is provided which is constituted by a base film 4 made of, for example, polyimide and sheets of copper foil 6 attached to both sides of the base film 4. Predetermined resists are applied over the sheets of copper foil 6 and are exposed to predetermined circuit patterns to provide masks having the circuit patterns. The sheets of copper foil 6 are then etched through the masks to provide the circuit patterns 8 (see FIG. 3B). At the same time, the sheet of copper foil 6, which is unnecessary, is removed from one side of the flexible section A.

Then, as illustrated in FIG. 3C, the cover lay film(s) 12 which are, for example, polyimide insulating film(s) are attached to the circuit pattern(s) 8 on one or both sides of the base film 4. The insulating layers 14 and 15 formed of, for example, glass-epoxy prepregs are attached to both sides of the rigid section B. The sheets of copper foil 16 are then laminated over the insulating layers 14 and 15. Next, as illustrated in FIG. 3D, the via hole 18 is formed at a predetermined position of the rigid section B by, for example, laser and other necessary through holes are formed by, for example, drilling.

In a subsequent desmearing process, the work is immersed in an alkaline chemical, such as sodium permanganate, to remove smears, such as debris, thereby cleaning inside the through holes and the via hole 18. Thereafter, the desmeared substrate is subject to necessary additional process steps, such as plating, resist application, exposure and etching, to complete the flex-rigid wiring board 2.

Patent Document 1 discloses a method for manufacturing a flex-rigid wiring board in which dissolution of a cover lay film during a desmearing process of a via hole resist layer of the flex-rigid wiring board is prevented. The disclosed method includes the following process steps: laminating, over the cover lay film, an adhesive layer which has an opening of a size corresponding to conductor wires in a flexible cable section; laminating, over the adhesive layer, an outer core substrate which has elongated holes extending in directions corresponding to circumferential edges of the opening, the elongated holes being located outside the circumferential edges of the opening formed in the adhesive layer and at boundaries of the rigid multilayer sections and the flexible cable section; laminating the via hole resist layer over the outer core substrate which constitutes the rigid multilayer sections and then subjecting the via hole resist layer to a desmearing process; and removing a portion of the outer core substrate laminated over the adhesive layer, the portion covering the opening of the adhesive layer and located between the elongated holes.

Patent Document 1: Japanese Patent Application Laid-open No. H11-68312

### SUMMARY OF THE INVENTION

### Problems to be Solved by the Invention

The method for manufacturing the related art flex-rigid wiring board illustrated in FIGS. 3A to 3D has the following problem: in the desmearing process, the base film 4 of the flexible section A is exposed to an alkaline chemical and is thereby dissolved or swollen. Especially recently, thinner flexible wiring boards and thus thinner base film 4 have been required. Such a thinner base film 4 is easily affected by alkaline chemicals. Impaired quality of the base film 4 of the flexible section A due to, for example, dissolution may have an adverse effect on the insulation performance of the flexible section A. As a result, short-circuits or breaking of the wiring of the copper foil may occur frequently.

It is necessary in the method disclosed in Patent Document 1 to include the process steps of: laminating the cover lay film made of, for example, polyimide with the outer core substrate via the adhesive layer for the protection of the cover lay layer from the chemical in the desmearing process; and removing the outer core substrate later. Thus, an increased number of process steps and an increased amount of materials are required, accompanying an increase in cost. As another problem, since the outer core substrate is attached to the cover lay film only with an adhesive, there is a possibility that the chemical may enter an adhesive section.

The present invention has been made in view of the foregoing background art and an object thereof is to provide a flex-rigid wiring board in which resin that is easily affected by chemicals can be protected reliably without any increase in the number of manufacturing process steps, and a method for manufacturing the flex-rigid wiring board.

### Means for Solving the Problems

The present invention is a method for manufacturing a flex-rigid wiring board consisting of a flexible section and a rigid section. The flexible section includes an insulating layer made of, for example, polyimide and a conductive layer formed by, for example, a sheet of copper foil. The rigid section is provided integrally with the flexible section and includes a wiring layer of a circuit. In the method, an intermediate process step, such as a desmearing process, using a chemical having resin solubility is performed in a state in which at least one surface of the insulating layer in the flexible section is entirely covered with the conductive layer.

The conductive layer covering the entire surface of the flexible section is removed after the intermediate process step. In particular, the conductive layer covering the entire surface of the flexible section is removed during a process step of forming the wiring layer in the rigid section after the intermediate process step.

Further, the present invention is a flex-rigid wiring board consisting of a flexible section and a rigid section. The flexible section includes an insulating layer and a conductive layer. The rigid section is provided integrally with the flexible section and includes a wiring layer of a circuit. At least one surface of the insulating layer in the flexible section is entirely covered with the conductive layer.

The conductive layer entirely covering at least one surface of the insulating layer is removed after an intermediate process step, and a portion of the conductive layer extending from the removed conductive layer extends into the rigid section at a boundary of the flexible section and the rigid section.

### EFFECT OF THE INVENTION

According to the flex-rigid wiring board and the method for manufacturing the same of the present invention, the resin film material can be protected reliably from the chemicals during the manufacture of the flex-rigid wiring board without any increase in the number of process steps. In addition, since the conductive layer used for the protection is removed in a later, existing process step, there is no increase in the number of the process steps.

Further, in the flex-rigid wiring board of the present invention, since the conductive layer extends into the rigid section, no chemical enters the flex-rigid wiring board at the boundary of the flexible section and the rigid section. Accordingly, the flexible section is protected even more reliably.

### BRIEF DESCRIPTION OF THE DRAWINGS

FIGS. 1A to 1C are schematic longitudinal sectional views illustrating process steps for manufacturing a flex-rigid wiring board according to an embodiment of the present invention.

FIGS. 2D to 2F are schematic longitudinal sectional views illustrating process steps subsequent to FIGS. 1A to 1C for manufacturing the flex-rigid wiring board according to the present embodiment.

FIGS. 3A to 3D are schematic longitudinal sectional views illustrating process steps for manufacturing a related art flex-rigid wiring board.

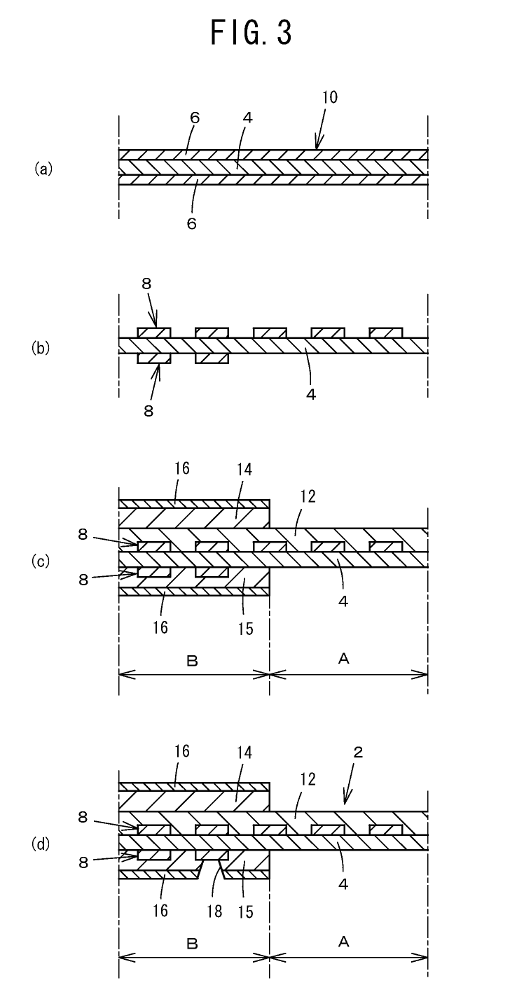

### DESCRIPTION OF EMBODIMENTS

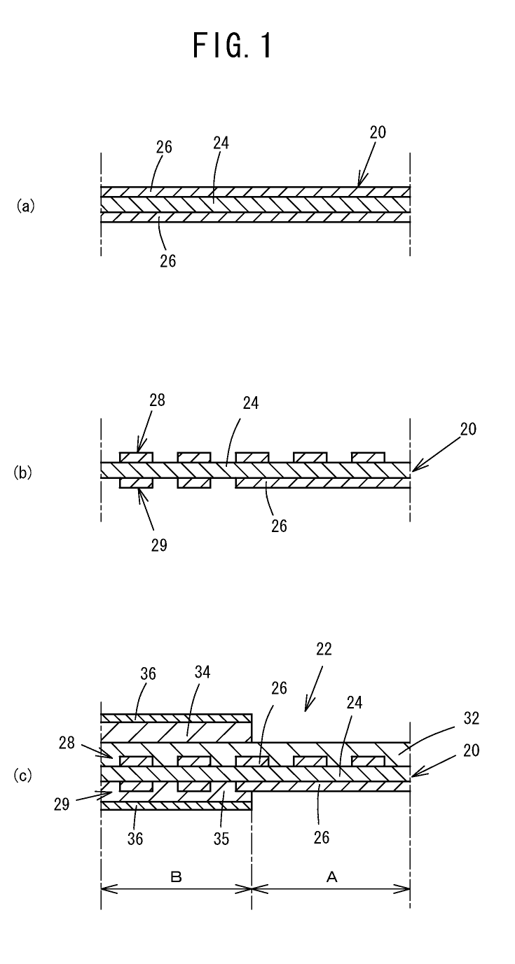

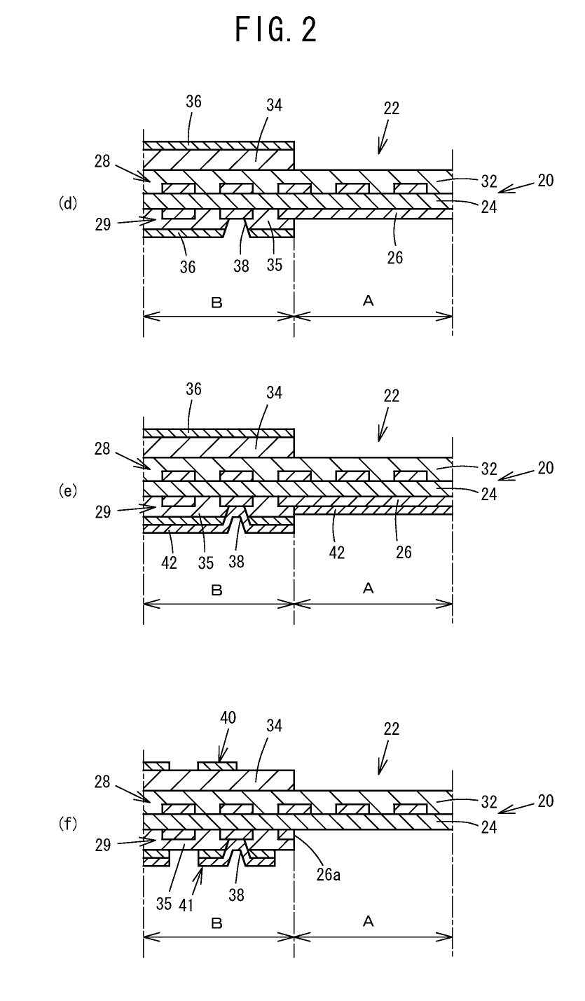

Hereinafter, an embodiment of a flex-rigid wiring board according to the present invention will be described with reference to FIGS. 1A to 1C and 2D to 2F. A flex-rigid wiring board 22 of the present embodiment consists of an elastic flexible section A and a stiff rigid section B on which electronic parts are mounted. The flexible section A and the mounting section B are integrally and continuously formed. A copper clad laminate 20 is provided at the center of the flex-rigid wiring board 22. The copper clad laminate 20 is constituted by a base film 24 as a core substrate and sheets of copper foil 26 attached to both sides of the base film 24. The base film 24 is, for example, a polyimide insulating layer and is, for example, about 10 to 50 micrometers thick. The sheets of copper foil 26 are conductive layers which are about several to several tens of micrometers thick.

A predetermined circuit pattern 28 formed of a wiring layer of copper foil is provided on one side of the copper clad laminate 20. A cover lay film 32 which is an insulating layer is laminated over the circuit pattern 28. The cover lay film 32 is made of, for example, polyimide and is thicker than the base film 24 by about ten to several tens of micrometers. The cover lay film 32 is attached with an adhesive to the circuit pattern 28 through thermo-compression bonding. In the flexible section A, a circuit pattern 28 as, for example, cables is formed by a sheet of copper foil 26 and the cover lay film 32 is exposed outside. In the rigid section B, a circuit pattern 40 of a sheet of copper foil 36 is formed over the cover lay film 32 via an insulating layer 34 which is, for example, a glass epoxy prepreg.

In the rigid section B, a predetermined circuit pattern 29 of the sheet of copper foil 26 is formed on the base film 24 on the side opposite to the cover lay film 32. In the flexible section A, the sheet of copper foil 26 remains on the entire surface and is exposed outside until in the middle of an intermediate process step. The sheet of copper foil 26 is removed from the entire surface in a later process step as will be described later. In the rigid section B, a circuit pattern 41 of the sheet of copper foil 36 is formed over an insulating layer 35. A via hole 38, an unillustrated through hole or other holes are formed in the rigid section B for the connection to the underlying circuit pattern 29. The cover lay film 32 may also be laminated over both sides of the base film 24.

A method for manufacturing the flex-rigid wiring board 22 is as follows: First, as illustrated in FIG. 1A, a copper clad laminate 10 is provided which is constituted by a base film 24 made of, for example, polyimide and sheets of copper foil 26 as conductive layers attached to both sides of the base film 24. Predetermined resists are applied over the sheets of copper foil 26. The resists are exposed to predetermined circuit patterns to provide masks having desired circuit patterns. The sheets of copper foil 26 are then etched through the masks to form the circuit patterns 28 and 29 (see FIG. 1B). At this time, as illustrated in FIG. 1B, the sheet of copper foil 26 on one of the sides of the flexible section A remains on the entire surface.

Then, as illustrated in FIG. 1C, the cover lay film 32 which is, for example, a polyimide insulating film is attached to the circuit pattern 28 on one side by thermo-compression bonding. The insulating layers 34 and 35 of, for example, glass epoxy prepregs, are attached to both sides of the rigid section B by compression bonding. The sheets of copper foil 36 are laminated over the insulating layers 34 and 35 by compression bonding. At a boundary of the rigid section B and the flexible section A where the prepreg insulating layer 35 terminates, an edge portion of the sheet of copper foil 26 which remains in the portion that will become the flexible section A extends into the rigid section B and is covered with the insulating layer 35.

In a subsequent intermediate process step, as illustrated in FIG. 2D, the via hole 38 is formed at a predetermined position in the rigid section B by, for example, laser and other necessary through holes are formed by, for example, drilling. Next, in a desmearing process, the work is immersed in an alkaline chemical, such as sodium permanganate, in order to remove smears, such as debris, inside the through holes and the via hole 38. Thus, inside of the via hole 38 is cleaned and, at the same time, roughened. Then, the sheet of copper foil 36 is plated with copper to form a conductive layer 42. As illustrated in FIG. 2E, the via hole 38 is filled with copper to provide a connection between the underlying circuit pattern 29 and the sheet of copper foil 36. Predetermined resists are applied over the sheets of copper foil 36. The resists are exposed to predetermined circuit patterns to provide masks having desired circuit patterns. The sheets of copper foil 36 are then etched through the masks to form the circuit patterns 40 and 41 (see FIG. 2F). The sheet of copper foil 26 and the conductive layer 42 of copper plating in the flexible section A are removed at this time while a portion 26a extending from the copper foil 26 of the flexible section A remains inside the rigid section B. After necessary additional process steps are performed, the flex-rigid wiring board 22 is completed.

According to the flex-rigid wiring board 22 of the present embodiment, the flex-rigid wiring board 22 can be manufactured with no substantial increase in the number of the process steps, and damages to the base film 24 during the desmearing process can be avoided reliably by the sheet of copper foil 26 that is not etched and thus remains on one side of the base film 24. The sheet of copper foil 26 which remains on the base film 24 is removed by etching in the later process step in which the circuit patterns 40 and 41 are formed. Accordingly, there is no increase in the number of the process steps for manufacturing the flex-rigid wiring board 22. Further, in the flex-rigid wiring board 22, since a portion of the sheet of copper foil 26 extends into the rigid section B, there is no possibility that the alkaline chemical enters the flex-rigid wiring board 22 at the boundary of the flexible section A and the rigid section B. Accordingly, there is no problem of, for example, dissolution within the flexible section A. Note that the cover lay film 32 is thicker than the base film 24 and is thus less easily affected by chemicals.

It should be noted that the flex-rigid wiring board and the method for manufacturing the same according to the present invention are not limited to those of the above-described embodiment. Components may be made of other materials and other lamination structures may be employed. For example, the insulating material is not limited to polyimide and may be polyester or a flexible glass epoxy material depending on the intended use. In addition to the copper foil, metal foil of gold and aluminum may also be employed as long as it protects the resin layer while remaining on the flexible section in the structure and processes similar to those in the above-described embodiment.

### REFERENCE NUMERALS

20 copper clad laminate
22 flex-rigid wiring board
24 base film
34, 35 insulating layer
26, 36 copper foil
28, 29, 40, 41 circuit pattern
A flexible section
B rigid section

1. A method for manufacturing a flex-rigid wiring board consisting of a flexible section and a rigid section,
the flexible section including an insulating layer and a conductive layer, and
the rigid section being provided integrally with the flexible section and including a wiring layer of a circuit, wherein
an intermediate process step using a chemical having resin solubility is performed, in a state in which at least one surface of the insulating layer in the flexible section is entirely covered with the conductive layer.

2. The method for manufacturing a flex-rigid wiring board according to claim 1,
wherein the intermediate process step is desmearing process of holes formed in the insulating layer performed after a process step of forming the holes in the insulating layer in the rigid section.

3. The method for manufacturing a flex-rigid wiring board according to claim 2,
wherein the conductive layer is formed after the intermediate process step by plating in the rigid section which includes the holes.

4. The method for manufacturing a flex-rigid wiring board according to claim 3,
wherein the conductive layer covering the entire surface of the flexible section is removed after the intermediate process step.

5. The method for manufacturing a flex-rigid wiring board according to claim 4,
wherein the conductive layer covering the entire surface of the flexible section is removed during a process step of forming the wiring layer in the rigid section, after the intermediate process step.

6. A flex-rigid wiring board consisting of a flexible section and a rigid section,
the flexible section including an insulating layer and a conductive layer, and
the rigid section being provided integrally with the flexible section and including a wiring layer of a circuit, wherein
at least one surface of the insulating layer in the flexible section is entirely covered with the conductive layer.

7. The flex-rigid wiring board according to claim 6, wherein
the conductive layer entirely covering at least one surface of the insulating layer is removed after an intermediate process step, and
a portion of the conductive layer extending from the removed conductive layer is located into the rigid section at a boundary of the flexible section and the rigid section.
